(19) United States
(12) Patent Application Publication
(10) Pub. No.: US 2025/0319538 A1
(43) Pub. Date: Oct. 16, 2025

(54) LASER BONDING DEVICE AND LASER BONDING METHOD

(71) Applicant: Samsung Display Co., LTD., Yongin-si (KR)

(72) Inventors: Tae Hee LEE, Yongin-si (KR); Byoung Yong KIM, Yongin-si (KR); Jae Gwang UM, Yongin-si (KR); Moon Won CHANG, Yongin-si (KR)

(21) Appl. No.: 19/046,228

(22) Filed: Feb. 5, 2025

(30) Foreign Application Priority Data
Apr. 11, 2024 (KR) 10-2024-0048506

(51) Int. Cl. B23K 1/005; B23K 1/20; B23K 3/04; B23K 101/38; H10H 29/01; H10H 29/34

(52) U.S. Cl. CPC B23K 1/0056; B23K 1/203; B23K 3/04; B23K 2101/38; H10H 29/012; H10H 29/345

(57) ABSTRACT

A laser bonding device includes: a support unit configured to fix a substrate thereon; a pressurized head module configured to fix a light emitting element as a bonding object; a laser generating unit configured to irradiate a laser beam to a bonding member for bonding the light emitting element and the substrate; a temperature sensor configured to measure the temperature of the bonding member; and a control unit configured to control a power and time of a laser beam irradiated to the light emitting element based on data received from the temperature sensor.

### CROSS-REFERENCE TO RELATED APPLICATION

The present application claims priority to and the benefit of Korean Patent Application No. 10-2024-0048506, filed on Apr. 11, 2024, in the Korean Intellectual Property Office, the entire disclosure of which is incorporated herein by reference.

### BACKGROUND

### 1. Field

Aspects of embodiments of the present disclosure relate to a laser bonding device and a laser bonding method.

### 2. Description of the Related Art

As the information society develops, the demand for display devices for displaying images in various forms is increasing. The display device may be a flat panel display, such as a liquid crystal display, a field emission display, a light emitting display, and the like.

### SUMMARY

A light emitting display device may include an organic light emitting display device including an organic light emitting diode element as a light emitting element and a micro light emitting display device including a micro light emitting diode element as a light emitting element. Because the micro light emitting diode element is made of inorganic materials, it exhibits less deterioration and a longer lifespan compared to an organic light emitting diode element.

Semiconductor elements, etc. may be bonded onto a substrate by laser bonding. Laser bonding is performed by irradiating a laser beam to a bonding member while pressing a semiconductor device on the substrate with a pressing member.

However, aspects and features of the present disclosure are not limited to those set forth herein. The above and other aspects and features of the present disclosure will become more apparent to one of ordinary skill in the art to which the present disclosure pertains by referencing the detailed description of the present disclosure given below.

According to an embodiment of the present disclosure, a laser bonding device includes: a support unit configured to fix a substrate thereon; a pressurized head module configured to fix a light emitting element as a bonding object; a laser generating unit configured to irradiate a laser beam to a bonding member for bonding the light emitting element and the substrate; a temperature sensor configured to measure the temperature of the bonding member; and a control unit configured to control a power and time of a laser beam irradiated to the light emitting element based on data received from the temperature sensor.

The control unit may be configured to control the pressure of the pressurized head module based on the data.

The laser bonding device may further include a pressure sensor configured to measure pressure applied to the bonding member.

The bonding member may include a first bonding member on one surface of the light emitting element and a second bonding member on a top surface of the substrate.

The temperature sensor may be configured to measure a temperature of the first bonding member.

A melting point of the first bonding member may be lower than or equal to a melting point of the second bonding member.

The control unit may be configured to determine a state of the bonding member by comparing the data with a table and to control the laser generating unit with a laser power and laser irradiation time according to the state of the bonding member, and the table may have a temperature range of a preheating zone of the bonding member and a temperature range of a reflow zone.

The control unit may be configured to control a laser power in the reflow zone to be lower than a laser power in the preheating zone.

The control unit may be configured to irradiate the laser beam in the reflow zone at first power for a first time and at a second power for a second time.

The second power may be lower than the first power.

The control unit may be configured to control a pressure of the pressurized head module in the reflow zone to be lower than a pressure of the pressurized head module in the preheating zone.

The control unit may be configured to control the laser power to gradually decrease as the bonding member changes state from a solid to a liquid.

The light emitting element may be a vertical light emitting element or a flip-type light emitting element.

A flux may be applied on the substrate.

The laser generating device may be configured to enable area heating for a target area.

According to another embodiment of the present disclosure, a laser bonding method includes: fixing a substrate to a support unit and fixing an interposer substrate having a light emitting element to a pressurized head module; lowering the pressurized head module such that the light emitting element touches the substrate; and melt-bonding the light emitting element to the substrate by irradiating a laser beam to a bonding member on a lower surface of the light emitting element. In the irradiating the laser beam, a temperature sensor measures a temperature of the bonding member and a control unit controls a power and time of a laser beam irradiated to the light emitting element based on data received from the temperature sensor.

In the irradiating the laser beam, the control unit controls a pressure of the pressurized head module based on the data.

The control unit determines a state of the bonding member by comparing the data with a table and controls the laser generating unit with a laser power and laser irradiation time according to the state of the bonding member. The table has a temperature range of a preheating zone of the bonding member and a temperature range of a reflow zone.

The control unit controls a laser power in the reflow zone to be lower than a laser power in the preheating zone.

The control unit controls a pressure of the pressurized head module in the reflow zone to be lower than a pressure of the pressurized head module in the preheating zone.

The method may further include, after the melt-bonding the light emitting element to the substrate, separating an interposer substrate from the light emitting element by raising the pressurized head module.

The method may further include applying a flux to the upper surface of the substrate, and after the separating the interposer substrate from the light emitting element, cleaning the flux on the substrate to which the light emitting element is bonded. Aspects and features of embodiments of the present disclosure provide a device and method for reducing or minimizing process defects in laser bonding that may be caused by a bonding member that reflows during laser bonding.

The laser bonding device and method according to embodiments of the present disclosure, reduce process defects in laser bonding by controlling the power and time of the laser beam according to the state of the bonding member during laser irradiation.

However, aspects and features of the present disclosure are not limited to the aforementioned aspects and features, and various other aspects and features are included in the present specification.

### BRIEF DESCRIPTION OF THE DRAWINGS

These and/or other aspects and features of the present disclosure will become apparent and more readily appreciated from the following description of embodiments, taken in conjunction with the accompanying drawings in which:

FIG. 1 is a perspective view of a display device according to one embodiment.

FIG. 2 is a layout diagram of a display device according to one embodiment.

FIG. 3 is a layout diagram of pixels of a display area according to one embodiment.

FIG. 4 is a cross-sectional view taken along the lines 11-11′ in FIG. 3.

FIG. 5 is a cross-sectional view of the area A in FIG. 4.

FIG. 6 is a layout diagram of pixels of a display area according to one embodiment.

FIG. 7 is a cross-sectional view taken along the line 12-12′ in FIG. 8.

FIG. 8 is a cross-sectional view of the area B in FIG. 7.

FIG. 9 is a diagram of a laser bonding device according to one embodiment.

FIG. 10 is a graph illustrating measured temperature over time in an ideal laser bonding process.

FIG. 11 is a graph illustrating measured temperature over time in the case of over-melting in a laser bonding process.

FIG. 12 is a graph illustrating the temperature of a bonding member according to time between laser bonding processes in a conventional laser bonding device.

FIG. 13 is a graph illustrating the temperature of a bonding member according to time between laser bonding processes of a laser bonding device according to one embodiment.

FIG. 14 is a flowchart describing a method of transferring a light emitting element according to one embodiment.

FIG. 15 is a flowchart describing a bonding method of a light emitting element according to one embodiment.

FIGS. 16 to 20 are diagrams showing steps of a method of transferring a light emitting element according to one embodiment.

### DETAILED DESCRIPTION

Embodiments of the present disclosure will now be described more fully hereinafter with reference to the accompanying drawings. The present disclosure may, however, be provided in various different forms and should not be construed as limited to the embodiments described herein.

Some of the parts which are not associated with the description may not be provided in order to describe embodiments of the disclosure.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Further, the phrase “in a plan view” means when an object portion is viewed from above, and the phrase “in a cross-sectional view” or “in a schematic cross-sectional view” means when a cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within about ±30%, 20%, 10%, 5% of the stated value.

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

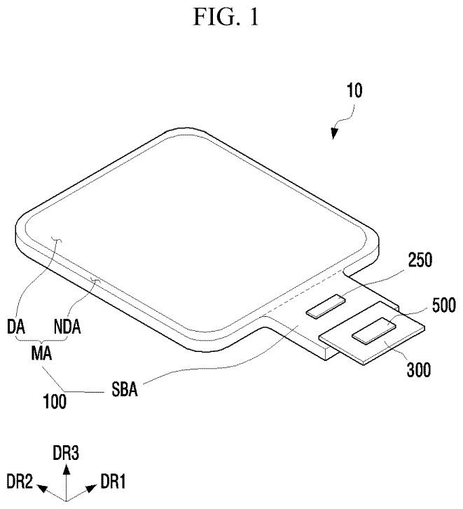

FIG. 1 is a perspective view of a display device according to one embodiment.

Referring to FIG. 1, a display device 10 is a device for displaying video and/or still images, such as mobile phones, smart phones, tablet personal computers, and portable electronic devices, such as smart watches, watch phones, mobile communication terminals, electronic notebooks, e-books, portable multimedia players (PMP), navigation devices, and ultra mobile PCs (UMPC), as well as display screens for a variety of products, such as televisions, laptops, monitors, billboards, and Internet of Things (IoT) devices.

The display device 10 may be a light emitting display device, such as an organic light-emitting display device including an organic light-emitting diode, a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the display device 10 will be described as a micro-light emitting display device as an example, but the present disclosure is not limited thereto. Hereinafter, an ultra-small light emitting diode is referred to as a light emitting element for ease of description.

The display device 10 includes a display panel 100, a display driving circuit 250, a circuit board 300, and a power supply circuit 500.

The display panel 100 may be formed as a rectangular plane having a short side in a first direction DR1 and a long side in a second direction DR2 that crosses (e.g., intersects) the first direction DR1. A corner at where the short side in the first direction DR1 and the long side in the second direction DR2 meet may be rounded to have a curvature (e.g., a predetermined curvature) or may be formed at a right angle. The planar shape of the display panel 100 is not limited to a square and may be other polygonal, circular, or oval shapes. The display panel 100 may be flat but is not limited thereto. For example, in other embodiments, the display panel 100 may be formed such that left and right ends have curved portions with a constant curvature or a changing curvature. In addition, the display panel 100 may be flexibly formed to be bent, curved, folded, or rolled.

The display panel 100 may have a main area MA and a sub-area SBA.

The main area MA may have a display area DA at where an image is displayed and a non-display area NDA that is a peripheral area of (e.g., that extends around) the display area DA. The display area DA may include a plurality of pixels that display an image. Each pixel may include a plurality of sub-pixels. For example, each of the pixels may include a first sub-pixel that emits first light, a second sub-pixel that emits second light, and a third sub-pixel that emits third light, but embodiments of the present disclosure are not limited thereto.

The sub-area SBA may protrude from one side of the main area MA in the second direction DR2. Although FIG. 1 illustrates an embodiment in which the sub-area SBA is unfolded, the sub-area SBA may be bent to be disposed on or under the bottom surface of the display panel 100. When the sub-area SBA is bent, it may overlap the main area MA in a third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 by using a chip on glass (COG) method, a chip on plastic (COP) method, or an ultrasonic bonding method, but the present disclosure is not limited thereto. For example, the display driving circuit 250 may be attached to the circuit board 300 by using a chip on film (COF) method.

The circuit board 300 may be attached to one end of the sub-area SBA of the display panel 100. Thereby, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible film, such as a flexible printed circuit board, a printed circuit board, or a chip on film.

The power supply circuit 500 may generate a plurality of panel driving voltages according to an external power supply voltage. The power supply circuit 500 may be formed as an integrated circuit (IC) and attached to the circuit board 300 by using a COF method.

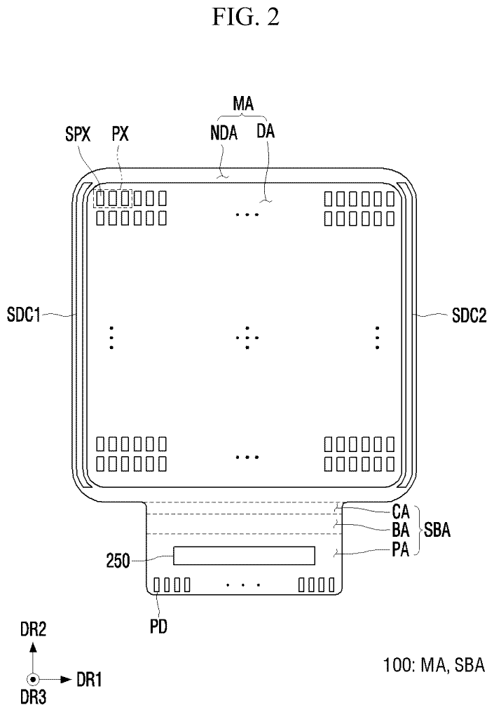

FIG. 2 is a layout diagram of a display device according to one embodiment. FIG. 2 illustrates the sub-area SBA in an unfolded state, that is, without being bent.

Referring to FIG. 2, the display panel 100 may have the main area MA and the sub-area SBA.

The main area MA may include the display area DA at where an image is displayed and the non-display area NDA that is a peripheral area of the display area DA. The display area DA may occupy most of the main area MA. The display area DA may be placed in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale light.

The non-display area NDA may be adjacent to the display area DA. The non-display area NDA may be an area outside the display area DA. The non-display area NDA may be arranged to surround (e.g., to surround a periphery of) the display area DA. The non-display area NDA may be an edge area of the display panel 100.

A first scan driving unit SDC1 and a second scan driving unit SDC2 may be disposed in the non-display area NDA. In the illustrated embodiment, the first scan driving unit SDC1 is disposed on one side (e.g., the left side) of the display panel 100, and the second scan driving unit SDC2 is disposed on the other side (e.g., the right side) of the display panel 100. However, the present disclosure is not limited to. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to the scan lines.

The sub-area SBA may protrude from one side of the main area MA in the second direction DR2. The length of the sub-area SBA in the second direction DR2 may be smaller than the length of the main area MA in the second direction DR2. The length of the first direction DR1 of the sub-area SBA is smaller than the length of the first direction DR1 of the main area MA or may be substantially equal to the length of the first direction DR1 of the main area MA. The sub-area SBA may be curved and may be disposed at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area at where the pads PD and the display driving circuit 250 are disposed. The display driving circuit 250 may be attached to the driving pads of the pad area PA by using a conductive adhesive member, such as an anisotropic conductive film. The circuit board 300 may be attached to the pads PD of the pad area PA by using a conductive adhesive member, such as an anisotropic conductive film. One side of the pad area PA may be in contact with the bending area BA.

The bending area BA is a bent area (e.g., an area configured to be bent). When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

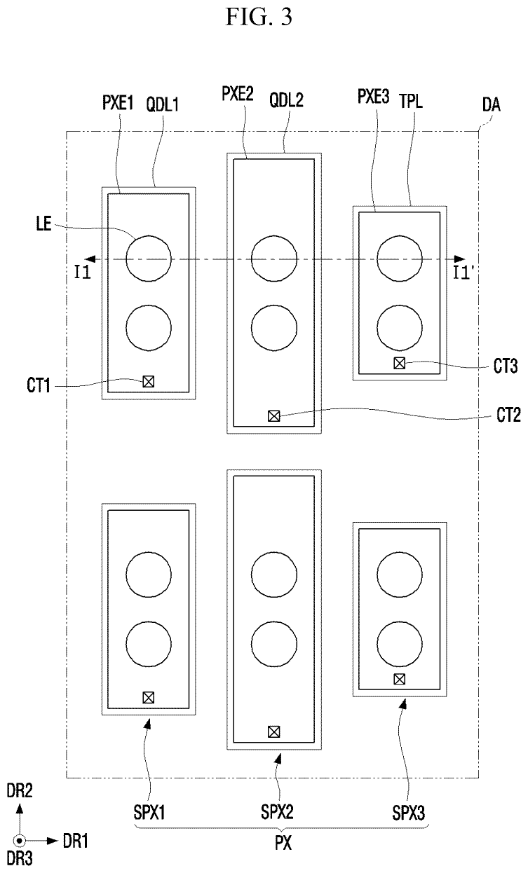

FIG. 3 is a layout diagram of pixels of a display area according to one embodiment.

Referring to FIG. 3, each of the plurality of pixels PX of the display area DA may include three sub-pixels SPX1, SPX2, and SPX3, but the present disclosure is not limited thereto, and in other embodiments, each of the plurality of pixels PX may include four sub-pixels. When each of the plurality of pixels PX includes three sub-pixels, each of the plurality of pixels PX may include the first sub-pixel SPX1, the second sub-pixel SPX2, and the third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged in (e.g., may be adjacent to each other in) a first direction DR1.

When each of the plurality of pixels PX includes three sub-pixels SPX1, SPX2, and SPX3, the first sub-pixel SPX1 may emit a first light, the second sub-pixel SPX2 may emit a second light, and the third sub-pixel SPX3 may emit a third light. The first color light may be light in a blue wavelength band, the second color light may be light in a green wavelength band, and the third color light may be light in a red wavelength band. For example, the blue wavelength band may refer to light having a main peak wavelength in a wavelength band from approximately 370 nm to approximately 460 nm, the green wavelength band may refer to light having a main peak wavelength in a wavelength band from approximately 480 nm to approximately 560 nm, and the red wavelength band may refer to light having a main peak wavelength in a wavelength band from approximately 600 nm to approximately 750 nm.

In another embodiment, when each of the plurality of pixels PX includes four sub-pixels, the first sub-pixel may emit a first light, the second and fourth sub-pixels may emit a second light, and the third sub-pixel may emit a third light. In another embodiment, the first sub-pixel may emit a first light, the second sub-pixel may emit a second light, the third sub-pixel may emit a third light, and the fourth sub-pixel may emit a fourth light. In such an embodiment, the fourth color light may be white light.

The first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer (or third light conversion layer) TPL.

Each of the first pixel electrode PXE1, the second pixel electrode PXE2, and the third pixel electrode PXE3 may have a rectangular planar shape with a short side in the first direction DR1 and a long side in the second direction DR2. An area of the first sub-pixel SPX1, an area of the second sub-pixel SPX2, and an area of the third sub-pixel SPX3 may be set depending on the light conversion efficiency of the first light conversion layer QDL1 and the light conversion efficiency of the second light conversion layer QDL2. For example, the lower the light conversion efficiency, the larger the area of the corresponding sub-pixel.

For example, as shown in FIG. 3, when the light conversion efficiency of the second light conversion layer QDL2 is lower than the light conversion efficiency of the first light conversion layer QDL1, the area of the second pixel electrode PXE2 may be larger than the area of the first pixel electrode PXE1. Also, the area of the first pixel electrode PXE1 may be larger than the area of the third pixel electrode PXE3 because the light transmission layer TPL transmits light from the light emitting element LE as it is (e.g., without conversion), whereas the first light conversion layer QDL1 needs to convert light.

Each of the pixel electrodes PXE1, PXE2, and PXE3 may be electrically connected to at least one transistor through a pixel connection hole (e.g., a pixel connection opening) CT1, CT2, and CT3.

A plurality of light emitting elements LE may be disposed on each of the pixel electrodes PXE1, PXE2, and PXE3. The same number of light emitting elements LE may be disposed on each of the pixel electrodes PXE1, PXE2, and PXE3. For example, two light emitting elements LE may be disposed on each of the pixel electrodes PXE1, PXE2, and PXE3. The plurality of light emitting elements LE may emit a third light, for example, light in a blue wavelength band, but the present disclosure is not limited thereto. When the light emitting element LE of the first sub-pixel SPX1 emits the first light, the light emitting element LE of the second sub-pixel SPX2 emits the second light, and the light emitting element LE of the third sub-pixel SPX3 emits the third light, the light conversion layers QDL1 and QDL2 and the light transmission layer TPL may be omitted.

The first light conversion layer QDL1 may completely (or entirely) overlap the first pixel electrode PXE1 and the plurality of light emitting elements LE of the first sub-pixel SPX1. The area of the first light conversion layer QDL1 may be larger than the area of the first pixel electrode PXE1. The first light conversion layer QDL1 may convert or shift the peak wavelength of incident light into light having another (e.g., a different) specific peak wavelength and emit it. For example, the first light conversion layer QDL1 may convert or shift the third light emitted from the plurality of light emitting elements LE of the first sub-pixel SPX1 into first light.

The second light conversion layer QDL2 may completely overlap the plurality of light emitting elements LE of the second pixel electrode PXE2 and the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into second light.

The light transmission layer TPL may completely overlap the plurality of light emitting elements LE of the third pixel electrode PXE3 and the third sub-pixel SPX3. The light transmission layer TPL may transmit incident light as it is (e.g., without conversion). For example, the light transmission layer TPL may directly transmit the third light emitted from the plurality of light emitting elements LE of the third sub-pixel SPX3.

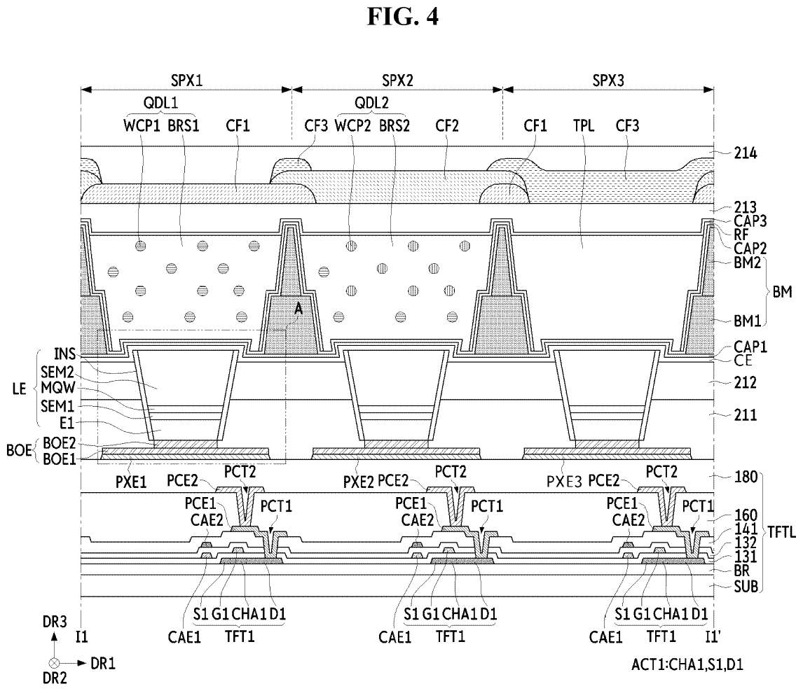

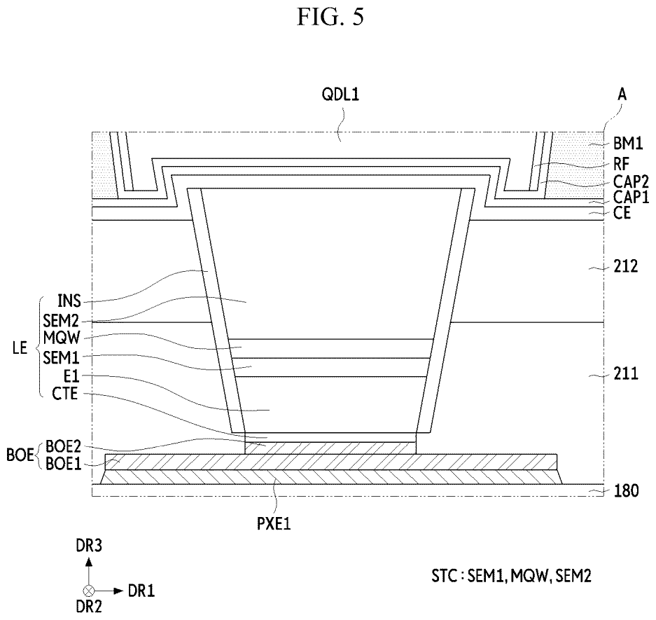

FIG. 4 is a cross-sectional view of a cross-section of a display panel taken along the lines 11-11′ in FIG. 3. FIG. 5 is a cross-sectional view of the area A in FIG. 4.

Referring to FIGS. 4 and 5, a substrate SUB may be made of an insulating material, such as glass, polymer resin, or the like. When the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be disposed on the substrate SUB. The barrier film BR is a film to protect the transistors of the thin film transistor layer TFTL and the light emitting elements LE disposed on the thin film transistor layer TFTL from moisture penetrating through the substrate SUB, which is vulnerable to moisture penetration. The barrier film BR may include (or may be composed of) a plurality of inorganic films alternately stacked on each other.

A thin film transistor TFT1 may be disposed on the barrier film BR. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, or amorphous silicon. In another embodiment, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1.

A first gate metal layer may be disposed on a first gate insulating film 131. The first gate metal layer may include the first gate electrode G1 and the first capacitor electrode CAE1 of the thin film transistor TFT1. The first gate electrode G1 may overlap the first active layer ACT1 in the third direction DR3.

In FIG. 4, the first gate electrode G1 and the first capacitor electrode CAE1 are shown as being disposed apart from each other, but the first gate electrode G1 and the first capacitor electrode CAE1 may be electrically or physically connected to each other. In another embodiment, the first gate electrode G1 and the first capacitor electrode CAE1 may not be electrically or physically connected to each other.

A second gate insulating film 132 may be disposed on the first gate electrode G1 and the first capacitor electrode CAE1 of the thin film transistor TFT1.

A second gate metal layer may be disposed on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate insulating film 132 has a dielectric constant (e.g., a predetermined dielectric constant), the capacitor may be formed by the first capacitor electrode CAE1, the second capacitor electrode CAE2, and the second gate insulating film 132 disposed between them.

A first interlayer insulating film 141 may be disposed on the second capacitor electrode CAE2.

A first data metal layer may be disposed on the first interlayer insulating film 141. The first data metal layer may include a first source connection electrode PCE1. The first source connection electrode PCE1 may be connected to the first drain area D1 of the first active layer ACT1 through a first source contact hole (e.g., a first source contact opening) PCT1 penetrating (or extending through) the first gate insulating film 131, the second gate insulating film 132, and the first interlayer insulating film 141.

A first planarization film 160 may be disposed on the first source connection electrode PCE1 to planarize a step formed by the thin film transistor TFT1.

A second data metal layer may be disposed on the first planarization film 160. The second data metal layer may include a second source connection electrode PCE2. The second source connection electrode PCE2 may be connected to the first source connection electrode PCE1 through a second source contact hole (e.g., a second source contact opening) PCT2 penetrating (or extending through) the first planarization film 160.

A second planarization film 180 may be disposed on the second source connection electrode PCE2.

The barrier film BR, the first gate insulating film 131, the second gate insulating film 132, and the first interlayer insulating film 141 may be formed as inorganic films, such as silicon nitride (SiNₓ), silicon nitride oxide (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or including multiple layers of any one of molybdenum (Mo), aluminum (Al), chromium (Cr), gold (Au), titanium (Ti), nickel (Ni), neodymium (Nd), and copper (Cu), or an alloy thereof.

The first planarization film 160 and the second planarization film 180 may be formed as an organic film, such as an acrylic resin, an epoxy resin, a phenolic resin, a polyamide resin, a polyimide resin, or the like.

A light emitting element layer may be disposed on the second planarization film 180. The light emitting element layer may include pixel electrodes PXE1, PXE2, and PXE3, light emitting elements LE, a common electrode CE, and organic layers 191, 192, and 210.

A pixel electrode layer may be disposed on the second planarization film 180. The pixel electrode layer may include a first pixel electrode PXE1, a second pixel electrode PXE2, and a third pixel electrode PXE3. Each of the pixel electrodes PXE1, PXE2, and PXE3 may be connected to the second source connection electrode PCE2 through a pixel connection hole (e.g., a pixel connection opening) penetrating (or extending through) the second planarization film 180. Each of the pixel electrodes PXE1, PXE2, and PXE3 may be connected to the first source area S1 or the first drain area S1 of the thin film transistor TFT1 via the first source connection electrode PCE1 and the second source connection electrode PCE2. Therefore, a voltage controlled by the thin film transistor TFT1 may be applied to each of the pixel electrodes PXE1, PXE2, and PXE3.

The pixel electrode layer may be formed as a single layer or including multiple layers of any one of molybdenum (Mo), aluminum (Al), chromium (Cr), gold (Au), titanium (Ti), nickel (Ni), neodymium (Nd), and copper (Cu), or alloys thereof. For example, the pixel electrode layer may be made of copper (Cu) having a relatively low sheet resistance to lower the resistance of each of the pixel electrodes PXE1, PXE2, and PXE3.

A bonding metal (also called a bonding member) BOE may be disposed on each of the pixel electrodes PXE1, PXE2, and PXE3. The bonding metal BOE may include a first bonding metal BOE1 disposed on each of the pixel electrodes PXE1, PXE2, and PXE3 and a second bonding metal BOE2 disposed on the first bonding metal BOE1. In another embodiment, one of the first bonding metal BOE1 and the second bonding metal BOE2 may be omitted. The second bonding metal BOE2 may be disposed in a smaller area than (e.g., may have a smaller surface area than) the first bonding metal BOE1.

The first bonding metal BOE1 and the second bonding metal BOE2 bond each of the pixel electrodes PXE1, PXE2, and PXE3 and the light emitting element LE disposed on the pixel electrodes PXE1, PXE2, and PXE3. The first bonding metal BOE1 and the second bonding metal BOE2 may be formed of gold (Au), copper (Cu), tin (Sn), silver (Ag), aluminum (Al), titanium (Ti), and the like.

A plurality of light emitting elements LE may be disposed on the first organic layer 210. FIG. 5 illustrates an embodiment in which each of the plurality of light emitting elements LE is a vertical-type micro LED extending in the third direction DR3. A vertical micro LED refers to an LED having a structure in which a first semiconductor layer SEM1, an active layer MQW, and a second semiconductor layer SEM2 are sequentially arranged in the vertical third direction (DR3).

Each of the plurality of light emitting elements LE may have an inverse tapered cross-sectional shape. For example, each of the plurality of light emitting elements LE may have a trapezoidal cross-sectional shape in which the upper surface is wider than the lower surface.

Each of the plurality of light emitting elements LE may be formed of an inorganic material, such as gallium nitride (GaN). Each of the plurality of light emitting elements LE may have a length in the first direction DR1, a length in the second direction DR2, and a length in the third direction DR3 of several to hundreds of μm, respectively. For example, each of the plurality of light emitting elements LE may have a length in the first direction DR1, a length in the second direction DR2, and a length in the third direction DR3 of approximately 100 μm or less.

Each of the plurality of light emitting elements LE may be formed by growing on (or being grown on) a semiconductor substrate, such as a silicon substrate or sapphire substrate. The plurality of light emitting elements LE may be directly transferred from the semiconductor substrate onto the pixel electrodes PXE1, PXE2, and PXE3 of the display panel 100. In another embodiment, the plurality of light emitting elements LE may be transferred onto the pixel electrodes PXE1, PXE2, and PXE3 of the display panel 100 through an electrostatic method using an electrostatic head or a stamp method using an elastic polymeric material, such as PDMS or silicone as a transfer substrate.

The light emitting element LE may include a conductive layer E1, a semiconductor stack STC, a contact electrode CTE, and a protective film INS. The semiconductor stack STC may include a first semiconductor layer SEM1, an active layer MQW, and a second semiconductor layer SEM2 sequentially arranged in the third direction DR3.

The conductive layer E1 may be disposed on the lower surface of the first semiconductor layer SEM1. Although FIG. 5 illustrates an embodiment in which the conductive layer E1 covers the entire lower surface of the first semiconductor layer SEM1, the present disclosure is not limited thereto. In one example, the conductive layer E1 may be disposed on a portion of the lower surface of the first semiconductor layer SEM1. The conductive layer E1 may include any one of molybdenum (Mo), aluminum (Al), chromium (Cr), gold (Au), titanium (Ti), nickel (Ni), neodymium (Nd), and copper (Cu).

The first semiconductor layer SEM1 may be disposed on the contact electrode CTE. A length of the bottom surface of the first semiconductor layer SEM1 in the first direction DR1 or the length in the second direction DR2 may be smaller than a length in the first direction DR1 or a length in the second direction DR2 of the contact electrode CTE. The first semiconductor layer SEM1 may include a semiconductor material layer doped with a first conductive dopant, such as magnesium (Mg), zinc (Zn), calcium (Ca), strontium (Sr), barium (Ba), or the like, such as gallium nitride (GaN).

The active layer MQW may be disposed on the first semiconductor layer SEM1. The active layer MQW may include the same semiconductor material layer as the first semiconductor material layer SEML1 and the second semiconductor material layer SEML2. For example, when the first semiconductor material layer SEML1 and the second semiconductor material layer SEML2 include gallium nitride (GaN), the active layer MQW may also include gallium nitride (GaN). For example, the active layer MQW may include at least one of gallium nitride (GaN), indium gallium nitride (InGaN), and aluminum gallium nitride (AlGaN). The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In such an embodiment, the well layer may be formed of InGaN and the barrier layer may be formed of GaN or AlGaN, but the present disclosure is not limited thereto. In another embodiment, the active layer MQW may have a structure in which semiconductor materials having a high band gap energy and semiconductor materials having a low band gap energy are alternately stacked with each other and may include other Group three to five semiconductor materials according to the wavelength range of emitted light.

When the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (light in the blue wavelength band) may be in a range of approximately 10 wt % to approximately 20 wt %.

The second semiconductor layer SEM2 may be disposed on the active layer MQW. The second semiconductor layer SEM2 may be a semiconductor material layer doped with a second conductivity type dopant, such as silicon (Si), germanium (Ge), tin (Sn), etc., for example, gallium nitride (GaN).

An electron blocking layer may be disposed between the first semiconductor layer SEM1 and the active layer MQW. The electron blocking layer may be a layer that suppresses or prevents too many electrons from flowing into the active layer MQW. For example, the electron blocking layer may be AlGaN or p-AlGaN doped with p-type Mg. In various embodiments, the electron blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN or GaN. In various embodiments, the superlattice layer may be omitted.

The protective film INS may be disposed on a side of the first semiconductor layer SEM1, a side of the active layer MQW, and a side of the second semiconductor layer SEM2. The protective film INS may be a film that protects the side surface of the light emitting element LE. The protective film INS may be formed of an inorganic film, such as silicon nitride (SiNₓ), silicon oxide (SiON), silicon oxide (SiOₓ), titanium oxide (TiOₓ), or aluminum oxide (AlOₓ).

A reflective layer surrounding (e.g., extending around) at least a portion of the side surface of the light emitting element LE may be further disposed on the protective film INS.

A third organic film 211 may be disposed to cover a portion of the side surfaces of the plurality of light emitting elements LE. Further, the third organic film 211 is disposed to cover the connection electrode BE, but at least a portion of the connection electrode BE may be exposed without being covered by the third organic film 211.

A fourth organic film 212 may be disposed on the third organic film 211. The fourth organic film 212 may be disposed to cover a portion of the side surface of each of the plurality of light emitting elements LE. The fourth organic film 212 may be disposed on at least a portion of the connection electrode BE that is exposed and not covered by the third organic film 211. The upper surface of each of the plurality of light emitting elements LE may be exposed without being covered by the fourth organic film 212.

The third organic film 211 and the fourth organic film 212 may be formed of an organic film, such as an acrylic resin, an epoxy resin, a phenolic resin, a polyamide resin, a polyimide resin, or the like.

The third organic film 211 and the fourth organic film 212 are layers for flattening steps formed by the plurality of light emitting elements LE. When the height of the third organic film 211 is set such that it covers most of the side surfaces of each of the plurality of light emitting elements LE, the fourth organic film 212 may be omitted.

The common electrode CE may be disposed on a top surface of each of the plurality of light emitting elements LE and the top surface of the fourth organic film 212. The common electrode CE may be a common layer commonly formed in the first sub-pixel SPX1, the second sub-pixel SPX2, and the third sub-pixel SPX3. The common electrode CE may be made of a transparent conductive material (TCO), such as indium tin oxide (ITO) and indium zinc oxide (IZO), that may transmit light.

The pixel electrodes PXE1, PXE2, and PXE3 may be referred to as an anode electrode or a first electrode, and the common electrode CE may be referred to as a cathode electrode or a second electrode.

A first capping layer CAP1 may be disposed on the common electrode CE.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be formed by dividing (e.g., may be formed in gaps in) the light blocking layer BM. Therefore, the first light conversion layer QDL1 may be disposed on the first capping layer CAP1 in the first sub-pixel SPX1, the second light conversion layer QDL2 may be disposed on the first capping layer CAP1 in the second sub-pixel SPX2, and the light transmitting layer TPL may be disposed on the first capping layer CAP1 in the third sub-pixel SPX3. The light blocking layer BM may overlap the third organic film 211 and the fourth organic film 212 in the third direction DR3 and may not overlap the plurality of light emitting elements LE.

The first light conversion layer QDL1 may convert a portion of the third light (e.g., light in the blue wavelength band) incident from the light emitting element LE into first light (e.g., light in the red wavelength band). The first light conversion layer QDL1 may include a first base resin BRS1 and first wavelength conversion particles WCP1. The first base resin BRS1 may include a light-transmitting organic material. The first wavelength conversion particles WCP1 may convert a portion of the third light (e.g., light in the blue wavelength band) incident from the light emitting element LE into first light (e.g., light in the red wavelength band).

The second light conversion layer QDL2 may convert a portion of the third light (e.g., light in the blue wavelength band) incident from the light emitting element LE into second light (e.g., light in the green wavelength band). The second light conversion layer QDL2 may include a second base resin BRS2 and second wavelength conversion particles WCP2. The second base resin BRS2 may include a light-transmitting organic material. The second wavelength conversion particles WCP2 may convert a portion of the third light (e.g., light in the blue wavelength band) incident from the light emitting element LE into second light (e.g., light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, or an imide-based resin. The first and second wavelength conversion particles WCP1 and WCP2 may be quantum dots QD, quantum rods, fluorescent materials, or phosphorescent materials.

The light blocking layer BM may include a first light blocking layer BM1 and a second light blocking layer BM2 that are sequentially stacked. A length in the first direction DR1 or a length in the second direction DR2 of the first light-receiving layer BM1 may be wider than a length in the first direction DR1 or a length in the second direction DR2 of the second light-receiving layer BM2. The first light blocking layer

BM1 and the second light blocking layer BM2 may be formed of an organic film, such as an acrylic resin, an epoxy resin, a phenolic resin, a polyamide resin, a polyimide resin, or the like. The first light blocking layer BM1 and the second light blocking layer BM2 may include a light blocking material that prevents light from the light emitting element LE of one sub-pixel from traveling to the neighboring sub-pixel. For example, the first light blocking layer BM1 and the second light blocking layer BM2 may include an inorganic black pigment, such as carbon black or an organic black pigment.

The second capping layer CAP2 may be disposed on the first capping layer CAP1 and the light blocking layer BM. The second capping layer CAP2 may be disposed on the side and top surfaces of the light blocking layer BM. In one embodiment, the second capping layer CAP2 may be disposed on the side of the first light blocking layer BM1 and the side and top surfaces of the second light blocking layer BM2.

The reflective film RF may be disposed between the light blocking layer BM and the first light conversion layer QDL1, between the light blocking layer BM and the second light conversion layer QDL2, and between the light blocking layer BM and the light transmission layer TPL. The reflective film RF may be disposed on the second capture layer CAP2 disposed on a side of the first light blocking layer BM1 and on a side of the second light blocking layer BM2. The reflective film RF reflects light traveling in the lateral direction from the first light conversion layer QDL1, the second light conversion layer QDL2, and the light transmission layer TPL.

The reflective film RF may include a highly reflective metal material, such as aluminum (Al). The thickness of the reflective film RF may be approximately 0.1 μm.

In another embodiment, the reflective film RF may include a first layer and a second layer of M (M being an integer of 2 or more) pairs having different refractive indices to act as Distributed Bragg Reflectors (DBR). In such an embodiment, M first layers and M second layers may be arranged alternately. The first and second layers may be formed of an inorganic film, for example, silicon nitride (SiNₓ), silicon nitride oxide (SiON), silicon oxide (SiOₓ), titanium oxide (TiOₓ), or aluminum oxide (AlOₓ).

The third capping layer CAP3 may be disposed on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ), silicon nitride oxide (SiON), silicon oxide (SiOₓ) or it may be formed of titanium oxide (TiOₓ) or aluminum oxide (AlOₓ). The first light conversion layer QDL1, the second capping layer CAP2, and the third capping layer CAP3 may be encapsulated by the first capping layer CAP1, the second capping layer CAP2, and the third capping layer CAP3.

A fifth organic film 213 may be disposed on the third capping layer CAP3. A plurality of color filters CF1, CF2, and CF3 may be disposed on the fifth organic film 213. The plurality of color filters CF1, CF2, and CF3 may include first color filters CF1, second color filters CF2, and third color filters CF3.

The first color filter CF1 disposed in the first sub-pixel SPX1 may transmit the first light (e.g., light in the red wavelength band) and may absorb or block the third light (e.g., light in the blue wavelength band). Therefore, the first color filter CF1 may transmit the first light (e.g., light in the red wavelength band) that has been converted by the first light conversion layer QDL1 from among the third light (e.g., light in the blue wavelength band) emitted by the light emitting element LE and may absorb or block the third light (e.g., light in the blue wavelength band) that has not been converted by the first light conversion layer QDL1. Accordingly, the first sub-pixel SPX1 may emit first light (e.g., light in a red wavelength band).

The second color filter CF2 disposed in the second sub-pixel SPX2 may transmit second light (e.g., light in the green wavelength band) and may absorb or block third light (e.g., light in the blue wavelength band). Therefore, the second color filter CF2 may transmit the second light (e.g., light in the green wavelength band) that has been converted by the first light conversion layer QDL1 from among the third light (e.g., light in the blue wavelength band) emitted by the light emitting element LE and may absorb or block the third light (e.g., light in the blue wavelength band) that has not been converted by the first light conversion layer QDL1. Accordingly, the second sub-pixel SPX2 may emit second light (e.g., light in the green wavelength band).

The third color filter CF3 disposed in the third sub-pixel SPX3 may transmit third light (e.g., light in the blue wavelength band). Therefore, the third color filter CF3 may transmit the third light (e.g., light in the blue wavelength band) emitted from the light emitting element LE through the light transmission layer TPL. Accordingly, the third sub-pixel SPX3 may emit third light (e.g., light in the blue wavelength band).

The first color filter CF1, the second color filter CF2, and the third color filter CF3 at where they overlap in the third direction DR3 may also overlap the light blocking layer BM in the third direction DR3.

A sixth organic film 214 for planarization may be disposed on the plurality of color filters CF1, CF2, and CF3.

The fifth organic film 213 and the sixth organic film 214 may be formed from an acrylic resin, an epoxy resin, a phenolic resin, a polyamide resin, a polyimide resin, or the like.

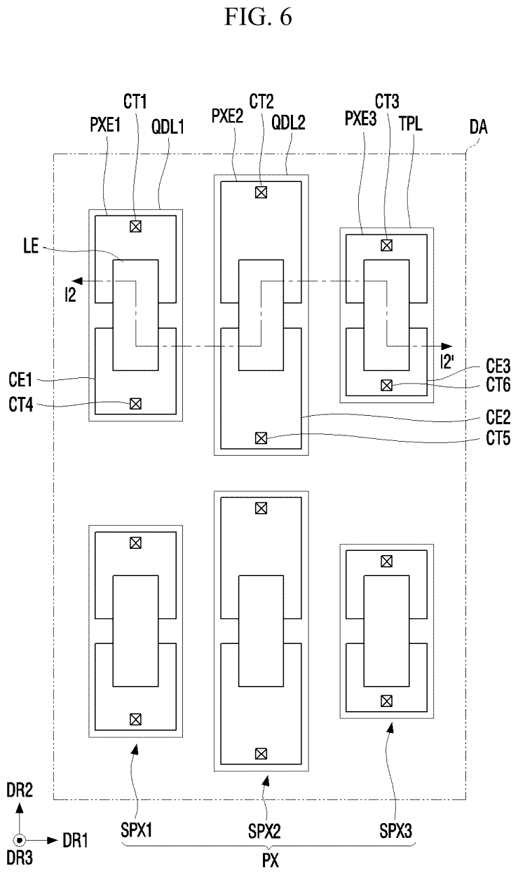

FIG. 6 is a layout diagram of pixels of a display area according to one embodiment.

The embodiment shown in FIG. 6 differs from the embodiment shown in FIG. 3 in that the light emitting element LE in each of the first sub-pixel SPX1, the second sub-pixel SPX2, and the third sub-pixel SPX3 is disposed on a common electrode CE1, CE2, and CE3 with the pixel electrodes PXE1, PXE2, and PXE3. In the embodiment shown in FIG. 6, descriptions that are the same or substantially similar to that of the embodiment shown in FIG. 3 may be omitted or only briefly provided.

Referring to FIG. 6, pixel electrodes PXE1, PXE2, and PXE3 and common electrodes CE1, CE2, and CE3 in each of the first sub-pixel SPX1, the second sub-pixel SPX2, and the third sub-pixel SPX3 may be arranged in the second direction DR2. Each of the pixel electrodes PXE1, PXE2, and PXE3 and the common electrodes CE1, CE2, and CE3 may have a rectangular planar shape, but the present disclosure is not limited thereto. Further, the area of the first pixel electrode PXE1 may be the same as the area of the first common electrode CE1, the area of the second pixel electrode PXE2 may be the same as the area of the second common electrode CE2, the area of the third pixel electrode PXE3 may be the same as the area of the third common electrode CE3, but the present disclosure are not limited thereto.

When the light conversion efficiency of the second light conversion layer QDL2 is lower than that of the first light conversion layer QDL1, the area of the second pixel electrode PXE2 may be larger than the area of the first pixel electrode PXE1 and the area of the second common electrode CE2 may be larger than the area of the first common electrode CE1. Also, because the light transmission layer TPL transmits the light of the light emitting element LE as it is (e.g., without conversion), while the first light conversion layer QDL1 converts the light, the area of the first pixel electrode PXE1 may be larger than the area of the third pixel electrode PXE3, and the area of the first common electrode CE1 may be larger than the area of the third common electrode CE3.

In the first sub-pixel SPX1, the first pixel electrode PXE1 and the first common electrode CE1 may be arranged to be spaced apart in the second direction DR2. In the second sub-pixel SPX2, the second pixel electrode PXE2 and the second common electrode CE2 may be arranged to be spaced apart in the second direction DR2. In the third sub-pixel SPX3, the third pixel electrode PXE3 and the third common electrode CE3 may be arranged to be spaced apart in the second direction DR2.

The first common electrode CE1 may be connected to the second power supply line VSL to which a second driving voltage VSS is applied through a first common connection hole (e.g., a first common connection opening) CT4. The second common electrode CE2 may be connected to the second power supply line VSL through a second common connection hole (e.g., a second common connection opening) CT5. The third common electrode CE3 may be connected to the second power supply line VSL through a third common connection hole (e.g., a third common connection opening) CT6. Therefore, the second driving voltage VSS may be applied to each of the common electrodes CE1, CE2, and CE3.

Because the pixel electrodes PXE1, PXE2, and PXE3 and the common electrodes CE1, CE2, and CE3 in each of the first sub-pixel SPX1, the second sub-pixel SPX2, and the third sub-pixel SPX3 are disposed on the pixel electrodes PXE1, PXE2, and PXE3 and the common electrodes CE1, CE2, and CE3 of the light emitting element LE, the length of the light emitting element LE in the second direction DR2 may be longer than the length in the first direction DR1.

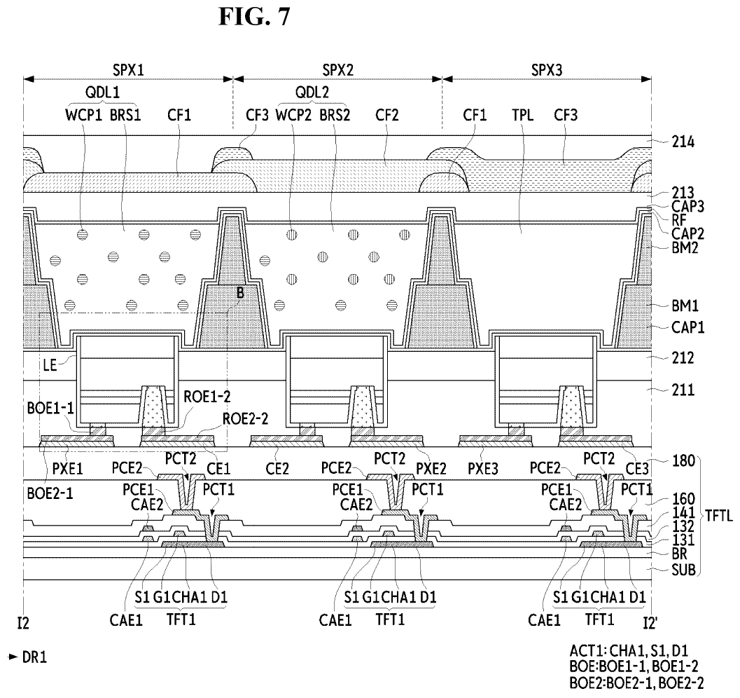

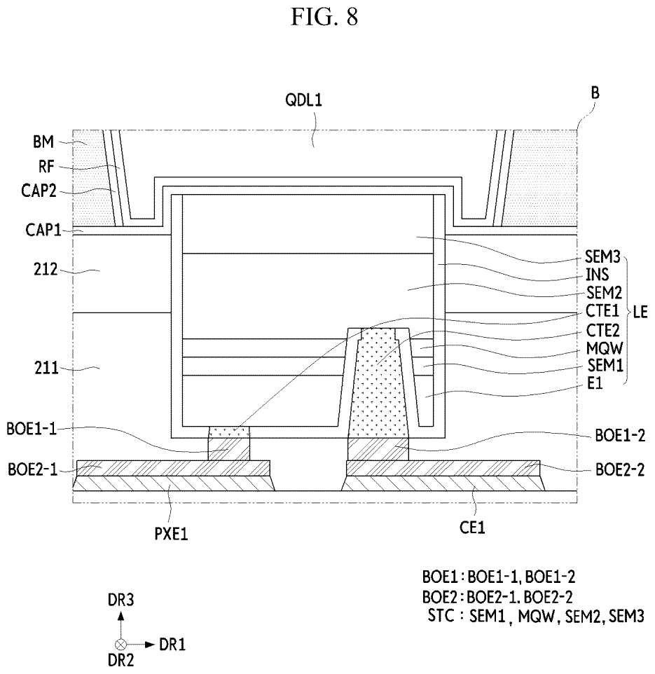

FIG. 7 is a cross-sectional view of a display panel taken along the line 12-12′ in FIG. 8. FIG. 8 is a cross-sectional view of the area B in FIG. 7.

The embodiments shown in FIGS. 7 and 8 are different from the embodiments shown in FIGS. 4 and 5 in that the light emitting element LE is a flip-type micro LED. In the embodiments shown in FIGS. 7 and 8, descriptions that are the same as or substantially similar to that of the embodiments shown in FIGS. 4 and 5 may be omitted or only briefly provided.

Referring to FIGS. 7 and 8, a pixel electrode layer including pixel electrodes PXE1, PXE2, and PXE3 and common electrodes CE1, CE2, and CE3 may be disposed on a second planarization film 180.

The light emitting element LE may be a flip-type micro LED. The flip-type micro LED refers to an LED in which contact electrodes CTE1 and CTE2 are formed on one side (e.g., the bottom side) of the light emitting element LE.

The semiconductor stack STC of the light emitting element LE may further include a third semiconductor layer SEM3. The third semiconductor layer SEM3 may be disposed on the second semiconductor layer SEM2.

The third semiconductor layer SEM3 may be referred to as an un-doped semiconductor layer, which is a semiconductor material layer in which the n-type dopant is lower than a reference (or predetermined) threshold. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), or indium nitride (InN), where the n-type dopant is lower than a reference threshold.

In FIG. 8, the protective film INS is disposed on the side surfaces of the first semiconductor layer SEM1, the side surfaces of the active layer MQW, and the side surfaces of the second semiconductor layer SEM2 of the semiconductor stack STC but not on the side surfaces of the third semiconductor layer SEM3. However, the present disclosure is not limited thereto. In one embodiment, the protective film INS is disposed on the side surfaces of the first semiconductor layer SEM1, the side surfaces of the second semiconductor layer SEM2, and the sides of the third semiconductor layer SEM3 of the semiconductor stack STC.

A hole (or opening) exposing the second semiconductor layer SEM2 may be formed through the conductive layer E1, the first semiconductor layer SEM1, and the active layer MQW of the light emitting element LE. The hole may have a circular shape in a plan view, but the present disclosure is not limited thereto. For example, the hole may have a polygonal shape in a plan view, such as an elliptical shape or a rectangular shape.

In addition, the protective film INS may be disposed on the sidewall of the conductive layer E1 exposed in the hole, the sidewall of the first semiconductor layer SEM1, and the sidewall of the active layer MQW. The protective film INS may not cover the second semiconductor layer SEM2 in the hole. Therefore, the second semiconductor layer SEM2 may be exposed without being covered by the protective film INS.

The first contact electrode CTE1 may be disposed on at least one side of the semiconductor stack STC and on at least one side and bottom of the conductive layer E1. The first contact electrode CTE1 may be disposed on the exposed lower surface of the conductive layer E1 that is not covered by the protective film INS. Therefore, the first contact electrode CTE1 may be electrically connected to the conductive layer E1.

The second contact electrode CTE2 may be disposed on at least one side of the semiconductor stack STC and on at least one side and bottom of the conductive layer E1. In such an embodiment, the first contact electrode CTE1 may be disposed on a first side of the semiconductor stack STC and a first side of the conductive layer E1, while the second contact electrode CTE2 may be disposed on a second side of the semiconductor stack STC and a second side of the conductive layer E1.

The second contact electrode CTE2 may be disposed on the protective film INS disposed in the hole and on the second semiconductor layer SEM2 exposed in the hole without being covered by the protective film INS. Therefore, the second contact electrode CTE2 may be electrically connected to the second semiconductor layer SEM2 in the hole.

The first contact electrode CTE1 and the second contact electrode CTE2 of each of the light emitting elements LE may be disposed on first bonding electrodes BOE1-1 and BOE1-2 and second bonding electrodes BOE2-1 and BOE2-2, respectively.

The first bonding electrode BOE1-1 and the second bonding electrode BOE2-1 connect the first contact electrode CTE1 and the pixel electrodes PXE1, PXE2, and PXE3.

The first bonding electrode BOE1-2 and the second bonding electrode BOE2-2 connect the second contact electrode CTE2 of the light emitting element LE and the common electrodes CE1, CE2, and CE3.

The first bonding electrodes BOE1-1 and BOE1-2 and the second bonding electrodes BOE2-1 and BOE2-2 may include any one of molybdenum (Mo), aluminum (Al), chromium (Cr), gold (Au), titanium (Ti), nickel (Ni), neodymium (Nd), and copper (Cu).

Hereinafter, the module and device for laser bonding of the light emitting element described with reference to FIGS. 1 to 8 will be described.

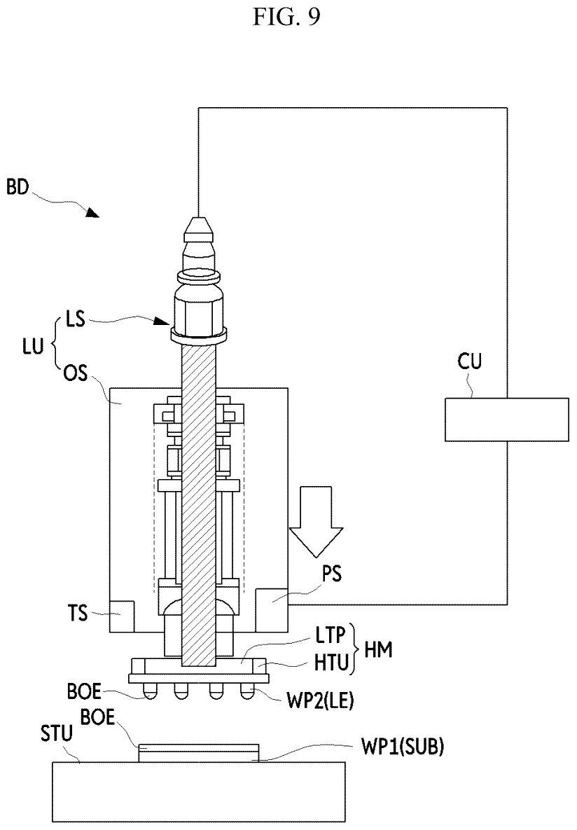

FIG. 9 is a diagram of a laser bonding device according to one embodiment.

Referring to FIG. 9, a laser bonding device BD may bond the light emitting element LE to a substrate SUB by irradiating a laser beam.

The laser pressure bonding device BD has a structure that allows heat and pressure to be applied to the substrate. For example, the laser pressure bonding device BD may bond two or more bonding objects WP1 and WP2 to each other by using a laser beam. The bonding objects WP1 and WP2 may be a substrate, a film, a display panel, a touch panel, or a semiconductor element, such as a printed circuit board, a flexible circuit board, or a light emitting element. For example, according to one embodiment, a first bonding object WP1 may be a substrate and a second bonding object WP2 may be a light emitting element, but the present disclosure is not limited thereto.

A flux F may be applied on the substrate SUB. The flux F may be a material that facilitates melt-bonding of the substrate SUB and the bonding member BOE in a bonding process by using a laser. The flux F may be oil-soluble or water-soluble and may include natural or synthetic resin. The flux F may be in liquid or gel form. The flux F is removed after the pressurized melting process is completed.

The flux F may be applied to have a thickness lower than that of the light emitting element LE. However, the thickness of the flux F may be the same as or thicker than the height of the light emitting element LE in some areas due to the arrangement of the light emitting element LE, etc.

The laser bonding device BD may include a laser generating unit LU, a pressurized head module HM, a temperature sensor TS, a pressure sensor PS, and a control unit CU. In one embodiment, the laser bonding device BD includes a temperature sensor TS and a pressure sensor PS as separate elements from the pressurized head module HM, but the present disclosure is not limited thereto. For example, in one embodiment, at least one of the temperature sensor TS and the pressure sensor PS may be included in the pressurized head module HM.

The laser generating unit LU may include a laser light source LS and an optical system OS.

The laser light source LS is a device configured to generate laser light by energy supplied from the outside and may be configured to generate laser light, for example, by using solid-state lasers such as YAG lasers, ruby lasers, glass lasers, YVO4 lasers, LD lasers, fiber lasers, liquid lasers, such as pigment lasers, CO₂ lasers, excimer lasers (ArF lasers, KrF lasers, XeCl lasers, XeF lasers, etc.), gaseous lasers, such as Ar lasers, He—Ne lasers, semiconductor lasers, free-electron lasers, etc.

The optical system OS may receive laser light in the form of a beam from the laser light source LS and may perform optical dispersion to enable area heating at a target area (e.g., a predetermined area).

For example, the optical system OS may include a beam shaper that converts a spot-shaped laser into a planar light source. Additionally, the optical system OS is disposed below the beam shaper and may further include a plurality of lens modules spaced apart from each other at an appropriate distance within the barrel. The surface light source emitted from the beam shaper may be controlled to be irradiated to the irradiation area of the bonding objects WP1 and WP2 by the plurality of lens modules.

The optical system OS may be raised or lowered along the third direction DR3 for alignment with the bonding objects WP1 and WP2, moved left or right along the first direction DR1, or moved along the second direction DR2 for adjusting the flatness of the bonding objects WP1 and WP2 and adjusting the height of the bonding objects WP1 and WP2.

The laser light emitted from the optical system OS may be irradiated to the bonding objects WP1 and WP2 and may heat a target area of the bonding objects WP1 and WP2. The laser light emitted from the optical system OS may be infrared laser light with a wavelength ranging from about 700 nm to about 1 mm. However, the present disclosure is not limited thereto.

In some embodiments, the temperature at which the bonding member BOE disposed between the bonding objects WP1 and WP2 is reflowed may be in a range of about 150° C. to about 280° C. Therefore, the output of the laser light source LS may be adjusted to achieve reflow of the bonding member BOE. The bonding member BOE may include at least one material selected from the group consisting of gold (Au), copper (Cu), aluminum (Al), and tin (Sn).

The bonding member BOE may be disposed on one or more of the first bonding object WP1 and the second bonding object WP2.

When the bonding member BOE is disposed on both the first bonding object WP1 and the second bonding object WP2, the melting point of the second bonding object WP2 may be lower than the melting point of the first bonding object WP1.

The laser light may heat the bonding member BOE to bond the bonding objects WP1 and WP2 to each other.

The support unit STU has an upper surface parallel to a plane defined by the first and second directions DR1 and DR2, which are perpendicular to each other. The first bonding object WP1 is seated on the upper surface of the support unit STU.

The support unit STU and the laser generating unit LU may be arranged on a straight line in the third direction DR3 to overlap each other on the plane. For example, the laser beam generated from the laser generating unit LU is irradiated in a direction toward the support unit STU.

In one embodiment, the support unit STU may be moved to a working position or a standby position by a separate rail or the like. For example, the support unit STU may move in the second direction DR2, that is, forward or backward, but the present disclosure is not limited to this.

The pressurized head module HM is disposed directly above the support unit STU and may adsorb and fix the second bonding object WP2. For convenience of explanation, the direction in which the laser beam is irradiated is defined as the downward direction, and the direction opposite to the downward direction is defined as the upward direction. In this embodiment, the upper direction and the lower direction are parallel to the third direction DR3, which is defined as a direction perpendicular to the first direction DR1 and the second direction DR2, respectively. The third direction DR3 may be a reference direction that distinguishes the front and back surfaces of components that will be described later. However, the terms upper or lower are relative concepts and may be converted to another direction.

The pressurized head module HM may further include a beam transmission plate LTP and a head transfer unit HTU.

The beam transmission plate LTP may be formed as a rectangular plane having a long side in the first direction DR1 and a short side in the second direction DR2 that crosses (e.g., intersects) the first direction DR1. A corner at where the long side in the first direction DR1 and the short side in the second direction DR2 meet may be formed at a right angle. The planar shape of the beam transmission plate LTP is not limited to a rectangle and may be formed into other polygonal, circular, or oval shapes.

The beam transmission plate LTP is formed of a rigid light-transmitting material and may be implemented as a base material that transmits laser light emitted from the laser generating unit LU.

The base material of the beam transmission plate LTP may be made of any beam transmitting material. The base material of the beam transmission plate LTP may be made of materials such as tempered glass, quartz, acrylic, metal oxides or oxides of semi-metals, for example, silicon oxide, aluminum oxide, etc. However, the present disclosure is not limited thereto.

The beam transmission plate LTP may include a chuck or the like with an adsorption head on one side. Through this adsorption head, the beam transmission plate LTP may adsorb and transport the second bonding object WP2.

The head transfer unit HTU moves the beam transmission plate LTP to the working or standby position. For example, the head transfer unit HTU may lower or raise the beam transmission plate LTP or move it to the left or right and then lower or raise it.

The pressure sensor PS may be implemented with at least one load cell, for example, but is not limited to this.

The pressure sensor PS may transmit a first measurement value generated by sensing to the control unit CU.

The temperature sensor TS may be a thermocouple. A thermocouple is a sensor made by bonding two different metals and is configured to measure temperature by measuring the potential difference (e.g., voltage) that occurs according to temperature changes. Thermocouples measure temperature using the principle of the thermoelectric effect of two metals. The thermoelectric effect is a phenomenon in which a potential difference occurs as electrons move when two or more different metals are joined and heat is transferred between metals. This thermoelectric effect is related to the temperature difference between two metals, and a thermocouple measures temperature using this phenomenon.

Thermocouples generally use metals such as platinum, tungsten, lead, copper, and constantan. When the temperature changes at the point where two metals are joined, a potential difference occurs due to the thermoelectric effect of the two metals. This potential difference may be measured to determine the temperature change.

The temperature sensor TS may transmit the second measurement value generated by the sensing to the control unit CU.

The control unit CU controls the overall operation and each component of the laser bonding device BD. For example, the control unit CU receives signals from the temperature sensor TS and the pressure sensor PS to determine the state of the bonding member BOE and controls the laser power of the laser generating unit LU and the laser irradiation time according to the state.

Further, in one embodiment, the control unit CU may control a pressurizing force on the pressurized head module HM.

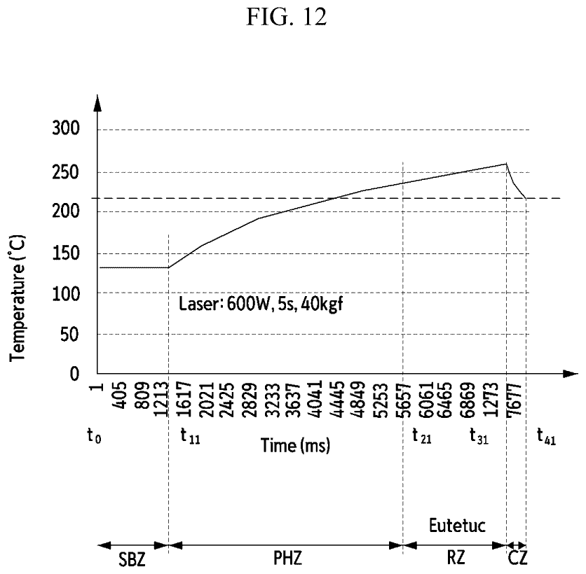

This will be described in detail with reference to FIGS. 12 to 20 described below.

The operations performed by the control unit CU may be decentralized by multiple physically separate computing units. Some of the operations performed by the control unit CU are performed by a first server and other operations are performed by a second server. In such an embodiment, the control unit CU may be implemented as an aggregation of physically separate computing devices.

The control unit CU, according to one embodiment of the present disclosure, may be implemented by a non-volatile memory configured to store data concerning an algorithm configured to control the behavior of various components of the laser bonding device BD or software instructions reproducing the algorithm, and a processor configured to perform the operations described below by using the data stored in the memory. In such an embodiment, the memory and processor may be implemented as separate chips. In another embodiment, the memory and processor may be implemented as a single chip integrated with each other. The processor may take the form of one or more processors.

The laser bonding device BU according to one embodiment may control the temperature and pressure (kgf) of heat applied to the bonding member according to the state of the bonding member by varying the laser power (W) and irradiation time (s) during the laser bonding process.

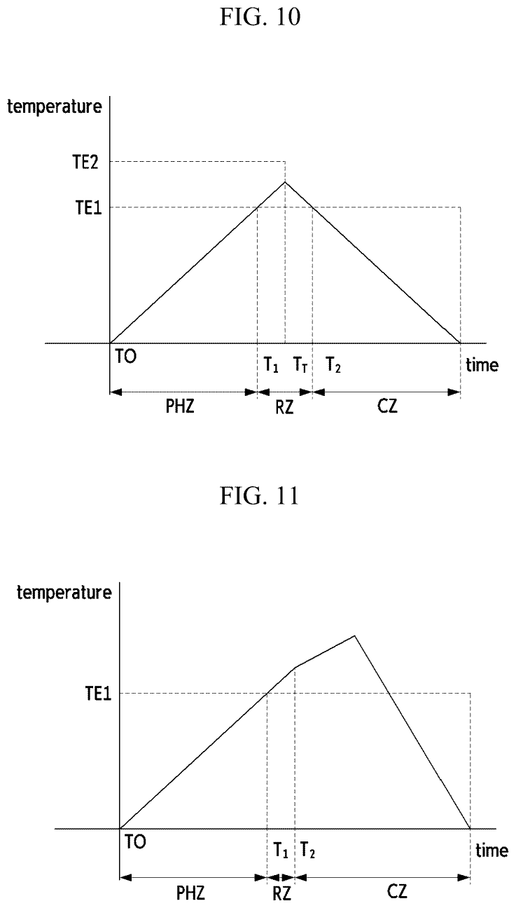

FIG. 10 is a graph illustrating measured temperature over time in an ideal laser bonding process. FIG. 11 is a graph illustrating measure temperatures over time to illustrate over-melting in a laser bonding process.

Referring to FIG. 10, this is a graph assuming that laser irradiation is started at the beginning of the bonding process and is stopped when the bonding member is completely reflowed.

The temperature of the bonding member increases steadily, peaks after a period of time when melting begins, and then falls steadily. For example, the bonding member starts to melt at a first temperature TE1, and the reflowed bonding member hardens as the temperature decreases. The first temperature TE1 may be about 230° C. but is not limited thereto and may vary depending on the type of bonding member.

The temperature TE2 is the highest temperature of the bonding member and may be about 250° C. but is not limited thereto, and the temperature may vary depending on the type of the bonding member. The time between the start of melting of the bonding member T₁ and the time until melting is completed T₂ before it is cured again may be referred to as the melting zone RZ.

The bonding process may include a preheating zone PHZ in which the bonding member is preheated from the start of laser irradiation until before it melts, a reflow zone RZ in which the bonding member is reflowed, and a cooling zone CZ in which the bonding member hardens. In the reflow zone RZ, the bonding member is in a solid state in areas other than the reflow zone RZ and is in a liquid state in the reflow zone RZ. The reflow zone RZ is very short compared to the entire bonding process section.

Referring to FIG. 11, when the laser continues to be irradiated even after the reflow zone RZ ends, for example, when the laser continues to be irradiated even after the bonding member is completely liquefied, the temperature may rise rapidly, causing the bonding member to over-melt, or the flux applied on the first bonding object WP1 to be hardened or carbonized, causing the flux to stick to the substrate of the first bonding object WP1. In these cases, the flux may not be able to be removed from the substrate by using normal cleaning processes. In serious cases, the substrate may be damaged by high temperatures.

If the laser irradiation is stopped before the bonding member is completely reflowed, bonding defects may occur. Examples of bonding defects include tilt, shift, and non-bonding of the second bonding object WP2. Here, tilt means that the second bonding object WP2 is not bonded horizontally to the first bonding object WP1 but is disposed to be tilted to one side. Shift means that the second bonding object WP2 is positioned away from the desired position. Non-bonding means that the second bonding object WP2 and the first bonding object WP1 are not completely bonded and, thus, electrically short-circuited.

As illustrated in FIG. 10, if the reflow zone RZ is very short, it is not easy to control the time to stop laser irradiation according to the time when the bonding member is completely reflowed.

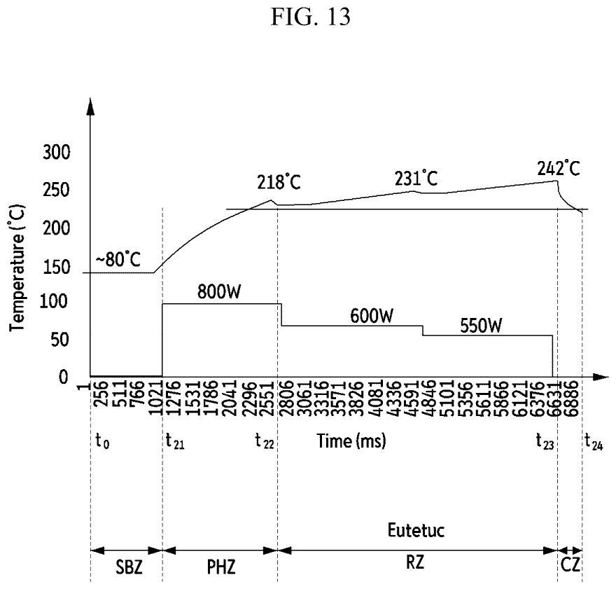

FIG. 12 is a graph illustrating the temperature of a bonding member according to time between laser bonding processes in a conventional laser bonding device. FIG. 13 is a graph illustrating the temperature of a bonding member according to time between laser bonding processes of a laser bonding device according to one embodiment.

Referring to FIG. 12, the laser bonding device irradiates a laser at the same laser power from the preheating zone PHZ to the reflow zone RZ and pressurizes the laser with the same pressure. For example, when a laser with a power of 600 W was irradiated for 5 seconds and pressurized with a pressure of about 40 kgf, the temperature of the bonding member was measured as a function of time. The laser irradiation starts at the first time t₁₁ and stops at the third time t₃₁ when the reflow zone RZ ends.

Referring to FIG. 13, the laser bonding device according to one embodiment may vary laser power and pressing force during the bonding process section. For example, in the preheating zone PHZ, a laser with a power of 800 W is irradiated for 2 seconds and pressurized with a pressure of 40 kgf. In the reflow zone RZ, first, a laser with a power of 600 W is irradiated for 2 seconds and pressurized with a pressure of 20 kgf, and then a laser with a power of 550 W is irradiated for 2 seconds and pressurized with a pressure of 10 kgf. In the cooling zone CZ, laser irradiation and pressurization are stopped.

FIG. 13 illustrates setting values for laser power, time, pressure, etc. for an arbitrary bonding member, and of course, the setting values may be changed if the type of bonding member changes. For example, when gold is used as a bonding member, a laser with a power of 1400 W is irradiated for 1.5 seconds in the preheating zone PHZ and pressurized with a pressure of 40 kgf. In the reflow zone RZ, first, a laser with a power of 800 W is irradiated for 2 seconds and pressurized with a pressure of 20 kgf, and then a laser with a power of 700W is irradiated for 2 seconds and pressurized with a pressure of 10 kgf. In the cooling zone CZ, laser irradiation and pressurization are stopped.

Comparing FIG. 13 with FIG. 12, when the laser power in the preheating zone PHZ is higher than the laser power in the reflow zone RZ, the reflow time may be accelerated. If the laser power is sequentially decreased within the reflow zone RZ, the reflow zone RZ may be maintained longer.

In addition, by gradually decreasing the pressing force in the reflow zone RZ, the pressing force of the bonding member in the reflow zone may be reduced.

By reducing the pressing force when the bonding member is in a reflow state, the rate of process defects, such as collapse, tilt, and shift, of the second bonding object WP2 that may occur during the bonding process may be reduced.

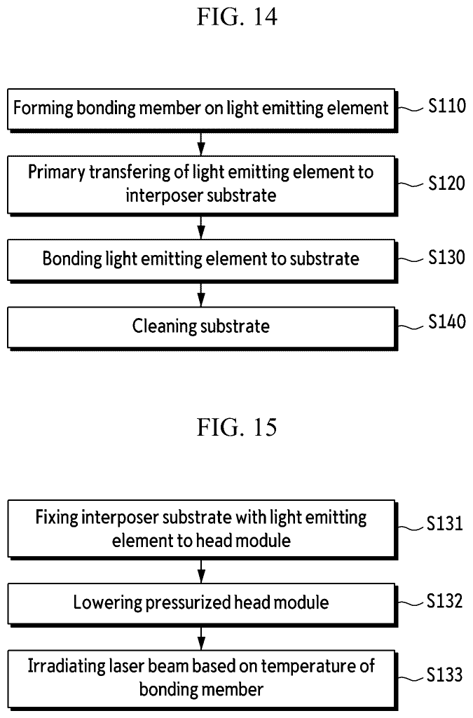

FIG. 14 is a flowchart describing a method of transferring a light emitting element according to one embodiment. FIG. 15 is a flowchart describing a bonding method of a light emitting element according to one embodiment. The bonding method of a light emitting element described with reference to FIG. 15 is a flowchart for explaining step S130 of the light emitting element transfer method described with reference to FIG. 14. The bonding method of the light emitting element shown in FIG. 15 is performed by a laser bonding device described with reference to FIGS. 9 to 13.

FIGS. 16 to 20 are diagrams illustrating steps of a method of transferring a light emitting element according to one embodiment. For example, FIGS. 16 to 20 respectively illustrate steps of a method of transferring the light emitting element LE in the form of a cross-sectional view.

Hereinafter, a light emitting element transfer method according to an embodiment will be described in conjunction with FIGS. 14 to 20.

First, referring to FIG. 16, a bonding member BOE1 is formed on a light emitting element LE grown on a growth substrate BSUB. (S110 in FIG. 14).

The light emitting element LE may correspond to the light emitting element LE described in FIGS. 5 and 8.

The light emitting element LE may be formed by growing on a growth substrate BSUB, such as a silicon substrate or sapphire substrate.

The light emitting element LE may include a conductive layer E1, a semiconductor stack STC, and a protective film INS. The semiconductor stack STC may include a first semiconductor layer SEM1, an active layer MQW, and a second semiconductor layer SEM2 sequentially arranged in the third direction DR3.

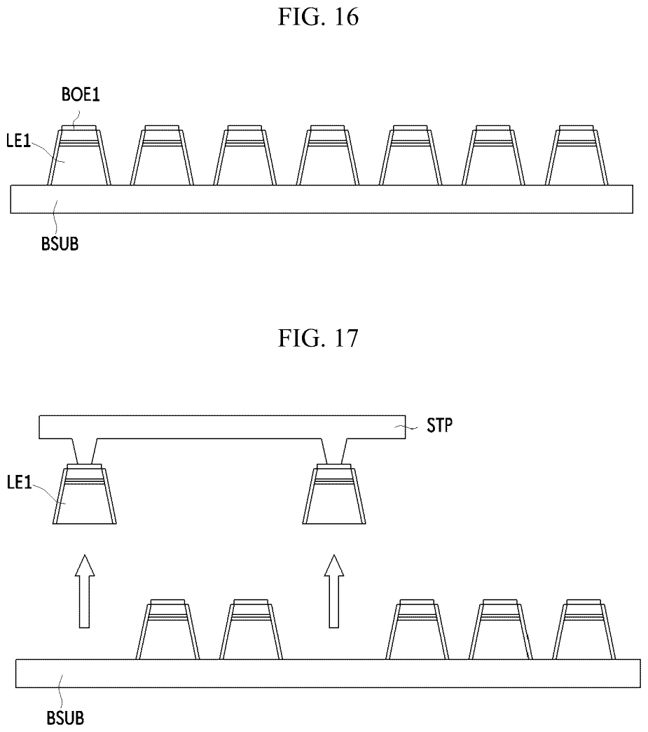

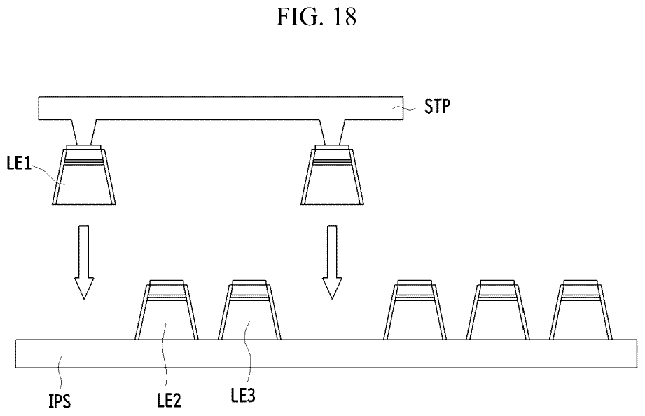

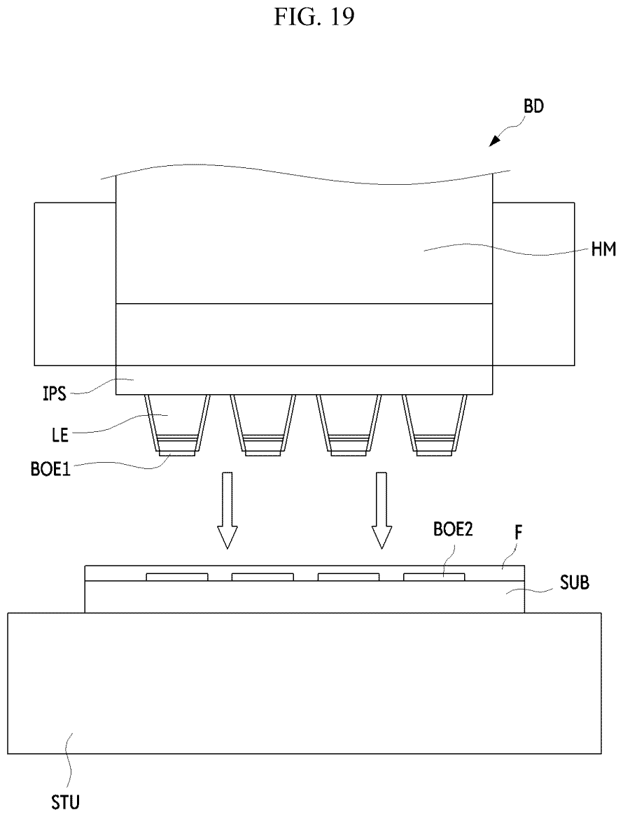

Referring to FIGS. 17 and 18, the light emitting element LE is transferred to the interposer substrate IPS. (S120 in FIG. 14)

The plurality of light emitting elements LE may be transferred onto the interposer substrate IPS through an electrostatic method by using an electrostatic head or a stamp method by using an elastic polymer material, such as PDMS or silicon as a transfer substrate.

The interposer substrate IPS may include (or may be composed of) a support layer and an adhesive layer disposed on the support layer. The support layer may be made of a material that is transparent and mechanically stable to allow light to pass therethrough. For example, the support layer may include a transparent polymer, such as polyester, polyacrylic, polyepoxy, polyethylene, polystyrene, polyethylene terephthalate, or the like. The adhesive layer may include an adhesive material for bonding the light emitting element LE. For example, the adhesive material may include urethane acrylate, epoxy acrylate, polyester acrylate, and the like. The adhesive material may be a material whose adhesive strength changes as ultraviolet rays (UV) or heat are applied thereto, and thus, the adhesive layer may be easily separated from the light emitting element LE.

Referring to FIG. 19, the light emitting element LE is bonded to the substrate SUB using a laser bonding device BD. (S130 in FIG. 14).

The laser bonding device BD may be the laser bonding device BD described with reference to FIG. 9.

To this end, the interposer substrate IPS having the light emitting element LE is fixed to the pressurized head module HM (S131 in FIG. 15). Additionally, the substrate SUB is fixed to the support unit STU.

A bonding member BOE2 may be further disposed on the substrate SUB. The bonding member BOE1 disposed on one surface of the light emitting element LE is referred to as a first bonding member BOE1, and the bonding member BOE2 disposed on the substrate SUB is referred to as a second bonding member BOE2 to distinguish between the bonding member BOE1 disposed on one side of the light emitting element LE and the bonding member BOE2 disposed on the substrate SUB. Here, first and second are only for distinction and do not have priority in order.

A flux F may be applied on the substrate SUB.

The light emitting element LE may touch the substrate SUB by lowering the pressurized head module HM. (S132 in FIG. 15).

A laser beam is irradiated based on the temperature of the bonding member BOE. (S133 in FIG. 15).

The control unit (CU in FIG. 9) controls the power and time of the laser beam based on received data. For example, the control unit CU determines the state of the bonding member BOE by comparing data with a table (e.g., a stored or preset table) and controls the laser generating unit (LU in FIG. 9) with a laser power and laser irradiation time according to the state of the bonding member BOE.

The table may include a temperature range of the preheating zone of the bonding member and a temperature range of the reflow zone.

Further, the control unit CU controls the pressure of the pressurized head module HM to adjust the pressure applied to the bonding member BOE. For example, when the bonding member BOE is in a liquid state, less pressure may be applied to the bonding member BOE than when the bonding member BOE is in a solid state.

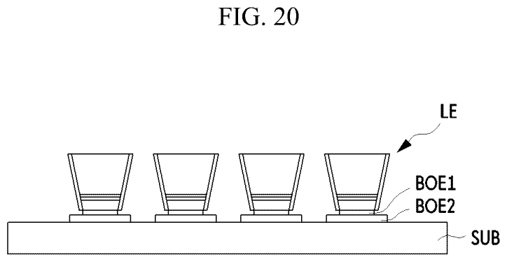

Referring to FIG. 20, the substrate SUB to which the light emitting element LE is bonded is cleaned. (S140 in FIG. 14).

After the bonding of the light emitting element LE on the substrate SUB is completed, the pressurized head module HM is raised to separate the interposer substrate ISP from the light emitting element. Further, the substrate SUB is cleaned to remove the flux F. The flux F is removed by a flux cleaner. The flux cleaner may be any suitable flux cleaner, such as an aqueous flux cleaner. For example, the flux cleaner may be CLEANTHROUGH 750HS, CLEANTHROUGH 750K of Kao Corporation, PINE ALPHA ST-100S of Arakawa Chemical Industries, Ltd. or the like but is not limited thereto. The cleaning conditions for cleaning the substrate SUB are not particularly limited. For example, the substrate SUB may be cleaned at a cleaning agent temperature in a range of about 30° C. to about 50° C. for about 1 minute to about 5 minutes (in one embodiment, at 40° C. for 2 to 4 minutes).

As described above, in bonding the light emitting element and the substrate by irradiating the bonding member with a laser beam, the power and time of the laser beam may be controlled according to the state of the bonding member during the laser irradiation to reduce the process defect of the laser bonding. Furthermore, the process defects in laser bonding may be reduced by controlling a pressurizing force on the bonding member according to the state of the bonding member during laser irradiation.

In concluding the detailed description, those skilled in the art will appreciate that many variations and modifications can be made to the embodiments described herein without substantially departing from the present disclosure. Therefore, the embodiments of the present disclosure described herein are used in a generic and descriptive sense and not for purposes of limitation.

What is claimed is:

1. A laser bonding device comprising:
a support unit configured to fix a substrate thereon;
a pressurized head module configured to fix a light emitting element as a bonding object;
a laser generating unit configured to irradiate a laser beam to a bonding member for bonding the light emitting element and the substrate;
a temperature sensor configured to measure the temperature of the bonding member; and
a control unit configured to control a power and time of a laser beam irradiated to the light emitting element based on data received from the temperature sensor.

2. The laser bonding device of claim 1, wherein the control unit is configured to control the pressure of the pressurized head module based on the data.

3. The laser bonding device of claim 1, further comprising a pressure sensor configured to measure pressure applied to the bonding member.

4. The laser bonding device of claim 1, wherein the bonding member comprises a first bonding member on one surface of the light emitting element and a second bonding member on a top surface of the substrate, and
wherein the temperature sensor is configured to measure a temperature of the first bonding member.

5. The laser bonding device of claim 4, wherein a melting point of the first bonding member is lower than or equal to a melting point of the second bonding member.

6. The laser bonding device of claim 1, wherein the control unit is configured to control a state of the bonding member by comparing the data with a table and to control the laser generating unit with a laser power and laser irradiation time according to the state of the bonding member, and
wherein the table stores a temperature range of a preheating zone of the bonding member and a temperature range of a reflow zone.

7. The laser bonding device of claim 6, wherein the control unit is configured to control a laser power in the reflow zone to be lower than a laser power in the preheating zone.

8. The laser bonding device of claim 7, wherein the control unit is configured to irradiate the laser beam in the reflow zone at first power for a first time and at a second power for a second time, and
wherein the second power is lower than the first power.

9. The laser bonding device of claim 6, wherein the control unit is configured to control a pressure of the pressurized head module in the reflow zone to be lower than a pressure of the pressurized head module in the preheating zone.

10. The laser bonding device of claim 1, wherein the control unit is configured to control a laser power to gradually decrease as the bonding member changes state from a solid to a liquid.

11. The laser bonding device of claim 1, wherein the light emitting element is a vertical light emitting element or a flip-type light emitting element.

12. The laser bonding device of claim 1, wherein a flux is applied on the substrate.

13. The laser bonding device of claim 1, wherein the laser generating device is configured to enable area heating for a target area.

14. A laser bonding method comprising:
fixing a substrate to a support unit and fixing an interposer substrate having a light emitting element to a pressurized head module;
lowering the pressurized head module such that the light emitting element touches the substrate; and
melt-bonding the light emitting element to the substrate by irradiating a laser beam to a bonding member on a lower surface of the light emitting element,
wherein, in the irradiating the laser beam, a temperature sensor measures a temperature of the bonding member and a control unit controls a power and time of a laser beam irradiated to the light emitting element based on data received from the temperature sensor.

15. The method of claim 14, wherein, in the irradiating the laser beam, the control unit controls a pressure of the pressurized head module based on the data.

16. The method of claim 14, wherein the control unit determines a state of the bonding member by comparing the data with a table and controls the laser generating unit with a laser power and laser irradiation time according to the state of the bonding member, and
wherein the table has a temperature range of a preheating zone of the bonding member and a temperature range of a reflow zone.

17. The method of claim 16, wherein the control unit controls a laser power in the reflow zone to be lower than a laser power in the preheating zone.

18. The method of claim 16, wherein the control unit controls a pressure of the pressurized head module in the reflow zone to be lower than a pressure of the pressurized head module in the preheating zone.

19. The method of claim 14, further comprising, after the melt-bonding the light emitting element to the substrate, separating an interposer substrate from the light emitting element by raising the pressurized head module.

20. The method of claim 19, further comprising applying a flux to an upper surface of the substrate; and
after the separating the interposer substrate from the light emitting element, cleaning the flux on the substrate to which the light emitting element is bonded.
